(19) United States
(12) Patent Application Publication
(10) Pub. No.: US 2001/0030024 A1
(43) Pub. Date: Oct. 18, 2001

(54) Plasma-enhanced processing apparatus

(75) Inventors: Yasumi Sago, Tokyo (JP); Kazuaki Kaneko, Tokyo (JP); Yoshikazu Nozaki, Tokyo (JP)

Correspondence Address: KANESAKA AND TAKEUCHI, 727 Twenty-Third Street South, Arlington, VA, 22202, US

(73) Assignee: Anelva Corporation

(21) Appl. No.: 09/809,274

(22) Filed: Mar. 16, 2001

(30) Foreign Application Priority Data
Mar. 17, 2000 (JP) 2000-76551

(51) Int. Cl. H01L 21/3065

(52) U.S. Cl. 156/345; 118/723 E

(57) ABSTRACT

This invention presents a plasma-enhanced processing apparatus, comprising; a process chamber in which a substrate is processed, a pumping system that pumps the process chamber, a gas-introduction system that introduces process gas into the process chamber, a plasma-generation means that generates plasma in the process chamber by applying energy to the process gas, a substrate holder that holds the substrate in the process chamber. An opposite electrode facing to the substrate held by the substrate holder is provided. The opposite electrode comprises a clamping mechanism that clamps the front board to support it. The opposite electrode comprises a main body, and a cooling mechanism that cools the front board via the main body. The clamping mechanism clamps the periphery of the front board by a clamping plate in surface contact with the front board. The clamping plate is flush with the front board.

### BACKGROUND OF THE INVENTION

The invention of this application relates to a plasma-enhanced processing apparatus that carries out a process on a substrate utilizing plasma.

Processes onto a substrate have been carried out variously and widely in manufacture of many kinds of semiconductor devices such as DRAM (Dynamic Random Access Memory)s, and liquid crystal displays(LCD). Such substrate processes sometimes use a plasma-enhanced processing apparatus where a substrate process is carried out utilizing plasma generated in a process chamber. For example, a plasma-enhanced etching apparatus is often used for etching through a mask pattern formed of photo-resist. The plasma-enhanced etching apparatus carries out the etching utilizing reaction of ions, activates or radicals produced in the plasma. Plasma-enhanced processing apparatuses have the merits that substrate contamination scarcely occurs because process is carried out under vacuum pressure, and fine-pattern formation is easy.

Plasma-enhanced processing apparatuses are divided into several types according to system of plasma generation. One type of apparatus has a couple of planar electrodes parallel to each other. One of electrodes is commonly used as a substrate holder that holds a substrate at a specific position. The front surface of the other electrode faces in parallel to the substrate. The other electrode is hereinafter called “opposite electrode”. In many cases, a high-frequency (HF) power source is connected with the electrode commonly used as the substrate holder. Here, frequencies between LF (Low Frequency) and UHF (Ultra-High Frequency) are defined as HF (High Efficiency). Plasma is generated by HF energy supplied from the HF power source. The opposite electrode is usually earthed. The HF electric field is perpendicular to the substrate, and uniform along directions parallel to the substrate. Therefore, ions in the plasma are accelerated perpendicularly and uniformly to the substrate. A highly efficient and uniform plasma-enhanced process can be carried out utilizing effect of ions incident on the substrate.

The opposite electrode is roughly composed of a front board facing to the substrate and a main body in contact with the front board. The main body is made of metal because it has the role of voltage introduction port for maintaining the front board at a specific potential. The front board is removable from the main body. This is because it is required to replace the front board to a new one. Replacement of the front board is from the following reason.

In plasma-enhanced processing apparatuses, the surface of an electrode is etched by incident ions from plasma, resulting in that it is eroded gradually. If the electrode is made of material that is not etched, deposition may occur on the electrode. For example, when plasma is formed of carbon fluoride gas, a carbon film is deposited on the electrode from decomposition of carbon fluoride gas in the plasma. Deposit on the electrode may peel off from internal stress or weight of itself, thus producing contaminants. The term “contaminant” in this specification generally means substance that may contaminate a substrate or a process. When a contaminant adheres to the substrate, sometimes a serious circuit defect such as disconnection may be brought. Contrarily, if the electrode is made of material capable of being etched such as silicon, deposition of product in the plasma is suppressed. Therefore, production of contaminants is suppressed as well.

When the front board is made of material capable of being etched as described, the front board is made thinner as the process is repeated. Therefore, it is necessary to replace the front board to a new one after repeating specific times of the processes. The front board is installed by screwing with the main body. The front board has a tapped hole, through which the front board is screwed.

In described conventional apparatuses, when plasma is generated, temperature of the front board increases, accepting heat from the plasma. Because the front board is completely fixed with the main body at positions of screwing, large internal stress is generated at those positions. Therefore, if the front board is made of fragile material such as silicon mono-crystal, the front board is sometimes cracked or broken before a replacement period.

If the front board is cracked or broken before a replacement period, it leads to increase of cost for the front boards. If the front board is broken while a substrate is processed, the broken front board may fall on the substrate under processing, destroying elements formed on the substrate. When it is worst, the substrate cannot be used no longer. As a result, large loss that makes the yield decrease much is brought. In addition, to resume the process requires steps of; temporarily venting the process chamber to open it to the atmosphere, eliminating the broken front board, and then pumping the process chamber again. This operation may make productivity much decrease because it takes long time.

Besides, temperature distribution on the front board tends to be out of uniform in the structure where the front board is screwed with the main body. The front board is in much more contact with the main body at the screwing area, contrarily being in less contact at the other area. When temperature of the front board increases by heat from the plasma, heat is transferred to the main body largely through the screwing area in much contact, contrarily transferred much less through the other area. As a result, temperature of the front board at the screwing area is lower than the other area, thus making temperature distribution on the front board out of uniform. If the main body has a cooling mechanism that cools the front board by depriving the front board of heat, this non-uniformity of temperature distribution becomes more serious.

Temperature of the substrate facing to the front board increases receiving heat from the front board. When temperature of the front board is out of uniform, temperature of the substrate becomes out of uniform as well. As a result, a process onto the substrate becomes out of uniform as well.

Taking the plasma-enhanced etching as an example, the above problem is described. Reaction in the plasma-enhanced etching is the one competing to the thin-film deposition by chemical substance produced in the plasma. The etching does not much depend on temperature because it is enabled mainly from effect of ion. On the other hand, the thin-film deposition highly depends on temperature because it is enabled from effect of neutral polymer or activate. If there is the relation that the deposition rate increases as temperature decreases, the thin-film deposition is not promoted on the high-temperature surface area of the front board. As a result, etching rate on the substrate becomes lower at the area facing to the low-temperature area of the front board, because neutral polymer or activate is deposited on the substrate to impede the etching. Therefore, etching rate on the substrate is lower at the area facing to the high-temperature area of the front board, and higher at the area facing the low-temperature area of the front board.

Not only the plasma-enhanced etching but also other plasma-enhanced processes have the described problem. Plasma-enhanced processing apparatuses comprising a front board facing to a substrate generally have the problem that temperature non-uniformity of the front board leads to non-uniformity of the substrate temperature, which deteriorates homogeneity of the substrate process.

### SUMMARY OF THE INVENTION

Object of this invention is to solve problems described above.

To accomplish this object, the invention presents a plasma-enhanced processing apparatus, comprising; a process chamber in which a substrate is processed, a pumping system that pumps the process chamber, a gas-introduction system that introduces process gas into the process chamber, a plasma-generation means that generates plasma in the process chamber by applying energy to the process gas, a substrate holder that holds the substrate in the process chamber, wherein an opposite electrode facing to the substrate held by the substrate holder is provided, and the opposite electrode comprises a clamping mechanism that clamps the front board to support it.

### BRIEF DESCRIPTION OF DRAWINGS

FIG. 1 is a front cross-sectional view of the plasma-enhanced processing apparatus of the first embodiment of the invention.

FIG. 2 is a cross-sectional view showing installation structure of the front board 5 in the apparatus shown in FIG. 1.

FIG. 3 is a plane view of the front board 5 in the apparatus shown in FIG. 1.

FIG. 4 is a cross-sectional view of the front board 5 shown in FIG. 3.

FIG. 5 explains the advantage with regard to temperature control of the front board 5, showing temperature change of the front board 5 in repeating the etching.

FIG. 6 is a front cross-sectional view of the main part of the plasma-enhanced processing apparatus of the second embodiment.

FIG. 7 is a front cross-sectional view of the main part of the plasma-enhanced processing apparatus of the third embodiment.

FIG. 8 is a front cross-sectional view of the main part of the plasma-enhanced processing apparatus of the fourth embodiment.

FIG. 9 shows result of an examination for relationship between screwing torque of the clamping plate 631 and contact of the front board 5 onto the main body 61.

FIG. 10 shows result of an examination for relationship between screwing torque of the clamping plate 631 and reproducibility of the etching.

### DETAILED DESCRIPTION OF PREFERRED EMBODIMENTS

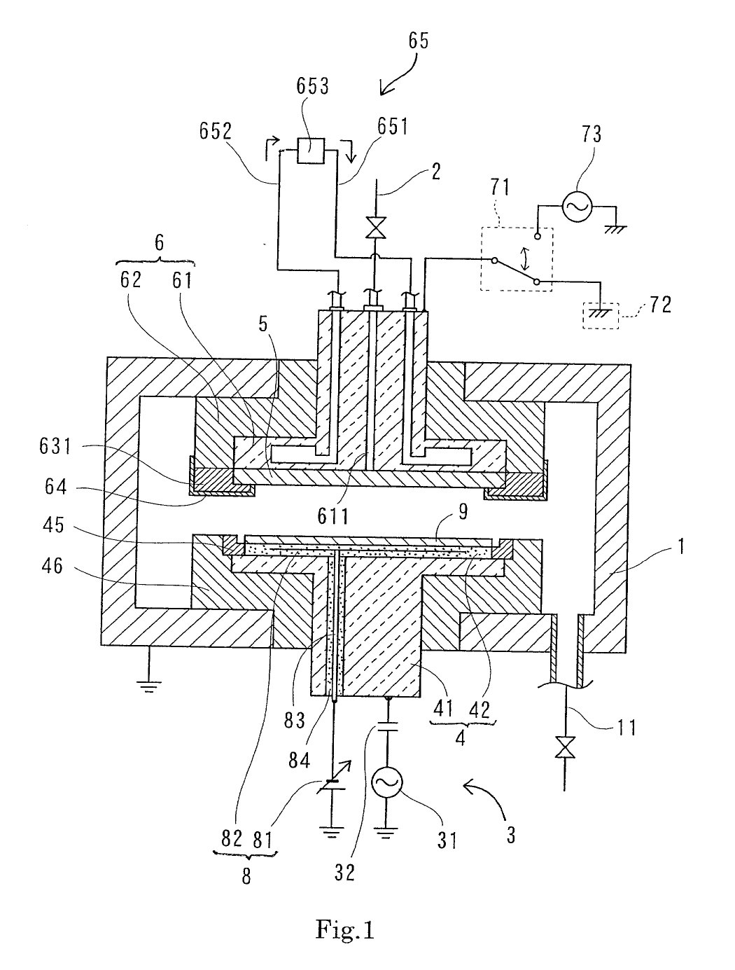

Preferred embodiments of the invention are described as follows. In the following description, plasma-enhanced etching apparatuses are adopted as examples of plasma-enhanced processing apparatuses. FIG. 1 is a front cross-sectional view of the plasma-enhanced processing apparatus of the first embodiment of the invention.

The apparatus shown in FIG. 1 comprises a process chamber 1 in which a substrate 9 is processed, a gas-introduction system 2 that introduces process gas necessary for plasma-enhanced etching into the process chamber 1, a plasma-generation means 3 that generates plasma in the process chamber 1 by applying energy to the process gas, a substrate holder 4 that holds the substrate 9 in the process chamber 1, and an opposite electrode 6 having a front board 5 facing to the substrate 9 held by the substrate holder 4.

The process chamber 1 is an airtight vacuum chamber, which is pumped by a pumping system 11. The process chamber 1, which is made of metal such as stainless steel, is electrically grounded. The pumping system 11, which comprises a vacuum pump (not shown) and pumping speed controller (not shown), can pump the process chamber 1 at a vacuum pressure from 10⁻³ Pa to 10 Pa.

The gas-introduction system 3 can introduce the process gas at a specific flow rate. In this embodiment, reactive gas such as CHF₃ is introduced into the process chamber 1 as component of the process gas. The gas-introduction system 2 comprises a gas bomb in which the process gas is stored, and a gas pipe interconnecting the gas bomb and the process chamber 1.

The plasma generation means 3 generates the plasma by applying HF energy to the introduced process gas. An HF source 31 is provided as a component of the plasma generation means 3. The HF source 31 is connected with the substrate holder 4. The HF source 31 is hereinafter called “holder-side HF source”. Frequency of the holder-side HF source 31 is in the range from 100 KHz to 100 MHz. There may be the case that a couple of HF sources which frequency is different from each other are connected in parallel. Output power of the holder-side HF source 31 may be about 300-2500 W. When the holder-side HF source 31 applies HF voltage with the substrate holder 4, HF discharge is ignited by HF field applied in the process chamber 1, thus generating the plasma. The substrate holder 4 and the front board 5 act as electrodes for sustaining the HF discharge.

The substrate holder 4 is roughly composed of a main bock 41 and holding block 42 in contact with the main bock 41. The main block 41, with which the the holder-side HF source 31 is connected, is made of metal such as aluminum or stainless steel. The holding block 42, on which the substrate 9 is held, is made of dielectric such as alumina.

An electro-static chucking mechanism 8 that chucks the substrate 9 by static electricity is provided with the substrate holder 4. The electro-static chucking mechanism 8 is roughly composed of a chucking electrode 82 provided in the holding block 42, and a chucking power supply 81 that applies negative direct voltage with the chucking electrode 82. An insulation tube 84 is provided in the substrate holder 4. The insulation tube 84 reaches the holding block 42, penetrating the main block 41. An introduction member 83 inserted into the insulation tube 84 is connected with the chucking electrode 82 at the one end. The other end of the introduction member 83 is connected with the chucking power supply 81.

A capacitor 32 is provided on the line interconnecting the holder-side HF source 31 and the substrate holder 4 on purpose that the holder-side HF source 31 can be commonly used as a self-bias power supply for giving the self-bias voltage to the substrate 9. When the plasma is generated in the process chamber 1 in state that the holder-side HF source 31 applies the HF field through capacitance, surface potential of the substrate 9 alters in the way that negative direct voltage is superimposed on alternating voltage. This negative direct voltage is the self-bias voltage.

A correction ring 45 is provided surrounding the top surface of the substrate holder 4. The correction ring 4 is made of the same material as the substrate 9, for example silicon mono-crystal. Temperature of the periphery of the substrate 9 tends to be lower than the center, because of heat diffusion from the edge of the substrate 9. The correction ring 45 makes temperature of the substrate 9 uniform by irradiating heat for offsetting heat diffusion from the edge.

The plasma generated in the process chamber 1 is sustained by ions and electrons released from the substrate 9 through the etching. Density of the plasma tends to be lower at the space region facing to the periphery of the substrate 9 than the space region facing to the center of the substrate 9. This is another reason why the correction ring 45 made of the same material as the substrate 9 is provided. The correction ring 45 supplies ions and electrons with the space region facing to the periphery of the substrate 9, thereby making the plasma density uniform.

The substrate holder 4 is installed with the process chamber 1 interposing an insulation block 46. The insulation block 46, which is made of insulator such as alumina, protects the main block 41 from the plasma as well as insulates the main block 41 from the process chamber 1. Vacuum seals such as O-rings are provided at the interface of the substrate holder 4 and the insulation block 46, and the interface of the process chamber 1 and the insulation block 46.

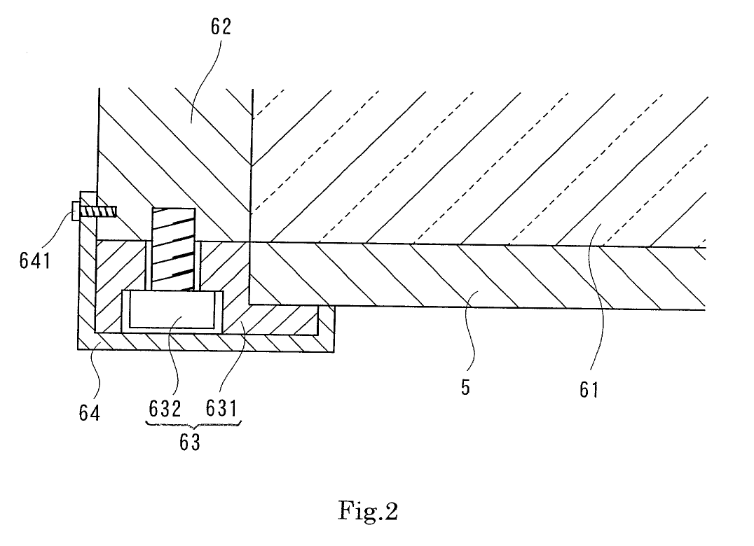

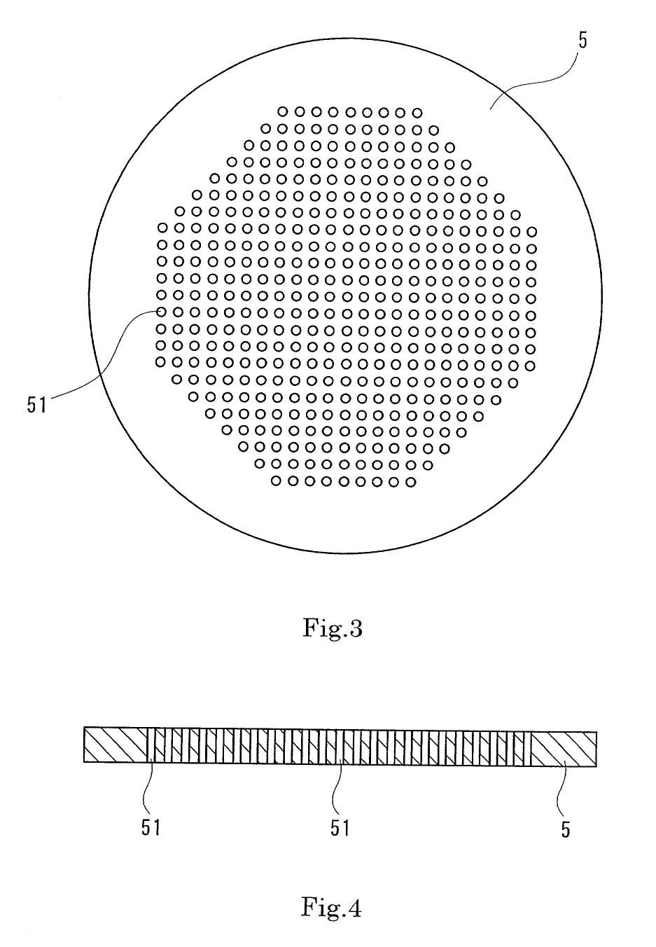

Next are described details of the front board 5 and the opposite electrode 6, which greatly characterize this embodiment. FIG. 2 is a cross-sectional view showing installation structure of the front board 5 in the apparatus shown in FIG. 1. FIG. 3 is a plane view of the front board 5 in the apparatus shown in FIG. 1. FIG. 4 is cross-sectional view of the front board 5 shown in FIG. 3.

In addition to the front board 5, the opposite electrode 6 in this embodiment comprises a main body 61 and an insulation casing 62 in which the main body 61 is stored. The process chamber 1 has an opening for installation of the opposite electrode 6. The opposite electrode 6 is installed airtightly on this opening, and projects downward in the process chamber 1.

As shown in FIG. 1, the front board 5 faces to the top surface of the substrate holder 4 in parallel. As shown in FIG. 3, the front board 5 is circular. The main body 61 is made of metal such as aluminum or stainless steel. As shown in FIG. 1, the main body 61, which cross-sectional shape is like reversed “T”, is composed of a circular board portion having the same radius as the front board 5, and an upright support portion which is coaxial with the circular portion.

An earthing part 72 and an extra HF source 73 are connected in parallel with the main body 61 interposing a switch 71. The switch 71 enables to select whether the main body 61 is maintained at the earth potential or applied HF voltage to. Frequency of the extra HF source is preferably different from the holder-side HF source 31. This is to prevent generation of high-energy load caused from interference of two HF waves. Frequency of the extra HF field 73 may be about 10-100 MHz. Output power of the extra HF field 73 may be about 300-3000 W.

When the extra HF source 73 is used for the plasma generation in addition to the holder-side HF source 31, it is enabled to make the plasma density higher, because HF energy applied to the plasma is increased. By this higher-density plasma, the etching rate is increased. The plasma may be generated only by the extra HF source 73. This case has the advantage that damage of the substrate 9 by charged particles from the plasma is suppressed because the plasma is generated limitedly at a spaces region adjacent to the front board 5, which is apart from the substrate 9.

In the case that HF voltage is applied to the main body 61, when the front board 5 is made of dielectric, the self-bias voltage is given to the down surface of the front board 5. Even in the case the front board 5 is made of conductor or semiconductor, when HF voltage is applied to it through capacitance, the self-bias voltage is given to the down surface of it as well. In the case that the main body 61 is earthed and the front board 5 is made of dielectric, the down surface of the front board 5 takes the floating potential.

A concavity (not shown) is provided at the down surface of the main body 61. This concavity is shallow, having depth of about 0.01-1.00 mm. The plane view of this concavity is coaxial with the front board 5 and slightly smaller than the front board 5 in radius. The front board 5 is in contact with the main body 61 at the outside of the concavity.

The point characterizing this embodiment greatly is that the described front board 5 is clamped by a clamping mechanism 63. The clamping mechanism 63 is roughly composed of a clamping plate 631 that covers the periphery of the front board 5, and a clamping screw 632 fastening the clamping plate 631 onto the main body 6. The clamping plate 631 is a ring-shaped member as a whole. The cross-sectional shape of the clamping plate 631 is composed of an upright portion and a level portion, being shaped “L” at the left side as shown in FIG. 2. The front board 5 is sandwich by the main body 61 and the level of the clamping plate 631.

The upper end of the clamping plate 631 is in contact with the bottom of the insulation casing 62. The clamping plate 631 is fastened on the insulation casing 62 by the clamping screw 632. A hole is tapped through the clamping plate 631 for fastening by the clamping screw 632. By this fastening, the front board 5 is clamped between the clamping plate 631 and the main body 61. For clamping the front board 5 adequately, the clamping plate 631 and the clamping screw 632 are made of metal such as stainless steel or aluminum, or ceramics.

The front board 5 is made of silicon poly-crystal as described. This is much relevant to that the front board 5 is not screwed but clamped by the clamping mechanism 63. The front board 5 is preferably made of material capable of being etched as described. As such the material, quartz, i.e. silicon oxide, or carbon is adopted conventionally. For example, in etching a silicon oxide film formed on the substrate 9, the front board 5 made of quartz is etched by the same mechanism as on the substrate 9. In the case that the front board is made of carbon, when plasma is generated introducing carbon fluoride gas, activates or ions from the plasma react with the front board 5 to produce volatile carbon fluoride, thus etching the front board 5.

However, even in the case the front board 5 is made of such quartz or carbon, the substrate 9 possibly may be contaminated. For example, when quartz is etched, silicon oxide is decomposed to release oxygen, which may cause the problem to oxidize the surface of the substrate 9. Taking this point into consideration, what has lowest probability to contaminate the substrate 9 is material just the same as the substrate 9. In this embodiment, the substrate 9 is supposed to be a silicon wafer. This is why silicon poly-crystal is chosen as material of the front board 5.

Because silicon poly-crystal is mechanically weak, conventionally it has not been chosen as material of the front board 5. However, in this embodiment, much inside stress is not generated in the front board because the front board 5 is only clamped by the clamping mechanism 63. Therefore, silicon poly-crystal can be chosen as material of the front board 5. As easily understood, even when silicon mono-crystal is chosen, the same effect as silicon poly-crystal can be obtained.

Instead of silicon poly-crystal and silicon mono-crystal, silicon carbide, silicon-doped silicon carbide, carbon, silicon nitride, alumina, sapphire, or quartz can be chosen as material of the front board 5. For structure of the front board 5, a silicon carbide film may be deposited on a body made of carbon, or the surface of a body made of carbon may be inverted to silicon carbide.

As shown in FIG. 2, the clamping plate 631 and the clamping screw 632 are covered by a protector 64. The protector 64 is to make the clamping plate 631 and the clamping screw 632 not exposed to the plasma. If the clamping plate 631 and the clamping screw 632 are exposed to the plasma, those are possibly etched, releasing material that could contaminate the substrate 9. If the clamping plate 631 and the clamping screw 632 is made of material that is not etched, when the clamping plate 631 and the clamping screw 632 are exposed to the plasma, products in the plasma are deposited, causing the problem that particles are produced from the peeled deposit. Considering this point, the protector 64 covers the clamping plate 631 and the clamping screw 632. The protector 64 is made of material that causes no problem if it is etched. Such material is quartz or carbon.

As shown in FIG. 2, the protector 64 is L-shaped in cross section and a ling-like member as a whole. The protector is also composed of an upright portion and a level portion. The protector 64 covers the clamping plate 631 and the clamping screw 632 at the level portion. The protector 64 is screwed at the upright portion with the insulation casing 62 by a screw 641. The screw 641 is preferable made of material not contaminating the substrate 9, as well as the protector 64. Still, the screw 641 may be made of stainless steel or aluminum because it is located at the position further from the plasma between the front board 5 and the substrate holder 4.

A cooling mechanism 65 is provided with the main body 61 of the opposite electrode 6. The cooling mechanism 65 cools the front board 5 by circulating coolant through the main body 61. The cooling mechanism 65 is roughly composed of a coolant supply pipe 651 that supplies coolant into a cavity in the main body 61, a coolant drainage pipe 652 that drains coolant from the cavity, a pump or circulator 653 for supply and drainage of coolant. As coolant, for example, Fluorinate manufactured by 3M corporation is used. The front board 5 is cooled at 90-150° C. via the main body 61 by such coolant kept at 20-80° C.

A sheet made of carbon (hereinafter called “carbon sheet”) is provided between the main body 61 and the front board 5. The carbon sheet is to enhance thermal contact of the front board 5 and the main body 61. The surfaces of the front board 5 and the main body 61 in contact with each other are not completely flat, i.e., slightly uneven. Therefore, there is a minute gap between the front board 5 and the main body 61. This gap has low thermal conductivity because it is under vacuum pressure. The carbon sheet is filled this gas with, thereby enhancing the thermal conductivity. A sheet formed of compressed carbon fiber can be used as the carbon sheet. Thickness of the carbon sheet is 0.02-4 mm, preferably 2 mm. Instead of the carbon sheet, a sheet made of conductive rubber or indium can be used for the same purpose.

A gas-flow path 611 is provided in the main body 61 so that the gas introduction system 2 can introduce the process gas into the process chamber 1. As shown in FIG. 1, the gas-flow path 611 is elongated vertically, penetrating through the main body 61. The gas pipe of the gas introduction system 2 is connected with the upper end of the gas-flow path 611.

The front board 5 presents routes for introducing the process gas into the process chamber 1. Concretely, as shown in FIG. 3 and FIG. 4, gas-introduction holes 51 are perforated with the front board 5. The gas-introduction holes 51 are penetrated through the front board 5 perpendicularly. Flowing through the gas-flow path 611 in the main body 61, the process gas is temporarily stored in a concavity provided at the down surface of the main body 61. The process gas in the concavity flows down through each gas-introduction hole 51 of the front board 5. As a result, the process gas is introduced uniformly to the space between the front board 5 and the substrate holder 4, at which the plasma is generated as described. The gas-introduction holes 51 are provided uniformly so that the process gas can be introduced uniformly. Specifically, as shown in FIG. 3, the gas-introduction holes 51 are provided at points corresponding to crossing points on an orthogonal lattice. Diameter of each gas-introduction hole 51 is 0.3-0.8 mm. Distance of neighboring two gas-introduction holes 51 is 8-15 mm.

Distance between the substrate holder 4 and the front board 5 is preferably 4-60 mm. If this distance is below 4 mm, the plasma hardly diffuses at the space. If this distance is over 60 mm, the plasma diffuses too broadly, making the plasma density lower. As a result, etching rate may decrease.

Size of the front board 5, i.e., area of the surface facing to the substrate 9, is preferably one to two times of the substrate 9. When the front board 5 is smaller than the substrate 9, the etching rate may decrease at the periphery of the substrate 9, causing non-uniformity of the etching rate, because the plasma density decreases at the space region adjacent to the periphery of the substrate 9. On the other hand, when the front board 5 is larger than two times of the substrate 9, the discharge space may be expanded wastefully, bringing the problem that size of the process chamber 1 is enlarged.

Next, operation of the plasma-enhanced apparatus of the first embodiment is described.

The substrate 9 is transferred into the process chamber 1 by the transferring mechanism (not shown), and placed at the substrate holder 4. Then, the electrostatic chucking mechanism 8 is operated to chuck the substrate 9 electro-statically on the substrate holder 4. The process chamber 1 is pumped at a specific vacuum pressure in advance. In this state, the gas introduction system 2 is operated to introduce the process gas into the process chamber 1. The holder-side HF source 31 is operated to apply HF power to the substrate holder 4, thereby igniting HF discharge with the process gas. Plasma is generated through the HF discharge. Radicals of the process gas are produced in the plasma. Simultaneously, the self-bias voltage is generated from mutual reaction of the HF field and the plasma. The self-bias voltage provides an electric field perpendicular to the substrate 9, accelerating ions in the plasma toward the substrate 9.

Utilizing energy of incident ions, the surface of the substrate is etched by reaction with the radicals. In short, reactive ion etching is carried out. After carrying out the etching for a required time, operations of the gas introduction system 2 and holder-side HF source are stopped. After pumping the process chamber 1 again, the substrate 9 is transferred out. Then, the next substrate 9 is transferred into the process chamber 1, and the same etching process is repeated. As the etching process is repeated many times, the protector 64 is etched to be thinner. Therefore, the protector 64 is replaced to a new one after specific times of the etching process.

In the above-described plasma-enhanced processing apparatus, because the front board 5 is not screwed but just clamped by the clamping mechanism 63, much internal stress is prevented from being generated locally in the front board 5. Therefore, accidents such as the front board breaking do not happen. By enlarging the contact area of the claming plate 631 and the front board 5, the front board 5 can be suspended more sufficiently in addition to reducing pressure given to the front board 5.

Because uniformity of pressure from the front board 5 onto the main body 61 is much improved in comparison with the screwing method, uniformity of thermal contact of the front board 5 onto the main body 61 is much improved as well. Therefore, when the front board 5 is heated by the plasma, uniformity of temperature distribution on the front board 5 is improved. As a result, uniformity of the etching onto the substrate 9 is improved as well.

In addition, by the described clamping mechanism 63, the front board 5 is fastened with higher force than the screwing method as a whole. In the case the front board 5 is screwed, if it is intended to increase the whole fastening force of the front board 5, it is unavoidable that pressure onto the main body 61 is increased at a screwing position because the front board 5 must be screwed tighter. However, the screwing force is limited to increase for preventing the front board breaking. Contrarily, in the case that the front board 5 is clamped by the clamping plate 631, which is in surface contact with the front board 5, problems such as the front board breaking do not arise even if it is fastened with higher force, because the force given to the front board 5 disperses.

Capability of pressing the front board 5 onto the main body 61 with higher force has the critical advantage with regard to temperature control of the front board 5. This point is described as follows.

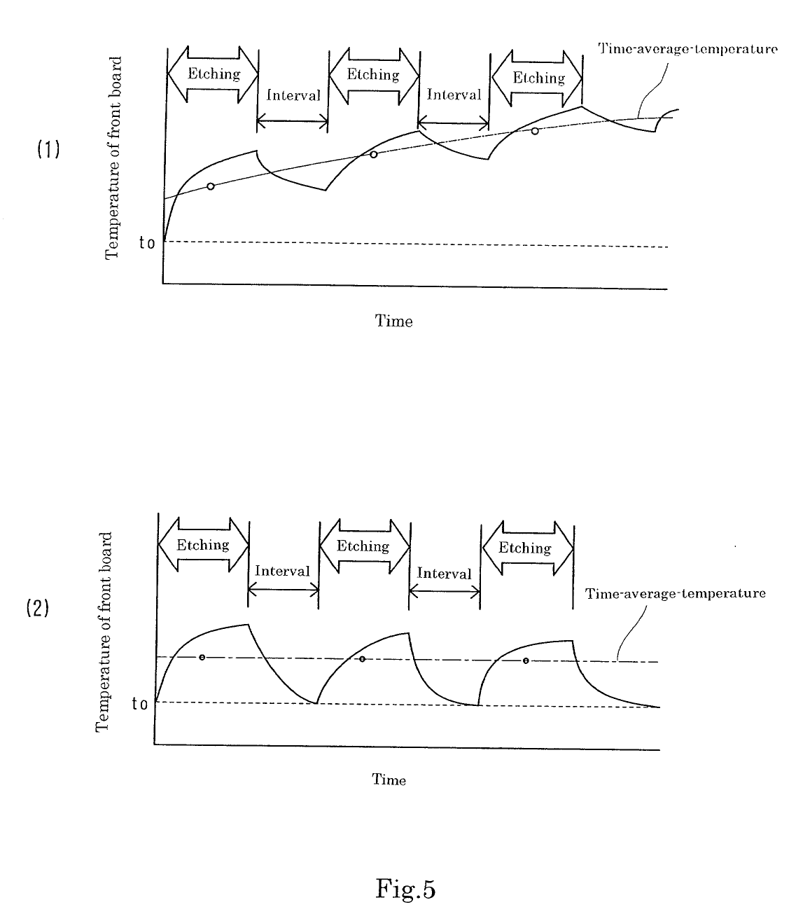

FIG. 5 explains the advantage with regard to temperature control of the front board 5, showing temperature change of the front board 5 in repeating the etching. FIG. 5(1) shows temperature change of the front board 5 screwed with the main body 61. FIG. 5(2) shows temperature change of the front board 5 clamped by the clamping mechanism 63.

As shown in FIG. 5(1), in the case that the front board 5 is screwed, temperature of the front board 5 increases throughout one time of the etching process without reaching thermal equilibrium, because of the bad thermal contact onto the main body 61. During the time until the next etching is started, hereinafter called “etching interval”, temperature of the front board 5 decreases because it is cooled down by the cooling mechanism 65. However, the front board 5 is not cooled down to the initial temperature to because of the bad thermal contact. The next etching is started in this state. During the next etching, temperature of the front board 5 increases again receiving heat from the plasma. The temperature reaches the maximum value at the time the etching is finished, which is hereinafter called “ultimate temperature”. The ultimate temperature in the next etching exceeds that in the former etching. With the same way, as the etching process is repeated, the ultimate temperature increases more and more.

In the apparatus where the front board 5 is screwed, therefore, average temperature tₐ of front board 5 within the time of the one etching process, hereinafter called “time-average temperature”, gradually increases as the etching process is repeated and repeated. After all, the time-average temperature tₐ reaches thermal equilibrium at a temperature, increasing no more. “Thermal equilibrium” here means that total quantity of heat given to the front board 5 within the time of the one etching process is equal to total quantity of heat simultaneously deprived the front board 5 of. Though the time-average temperature reaches the thermal equilibrium, total quantity of heat given to the substrate 9 from the front board 5 within the time of each etching process differs until then, because the time-average temperature tₐ differs. As a result, etched quantity in each etching process may differ.

As a method to make the time-average temperature constant in the apparatus where the front board 5 is screwed, aging of the front board 5 may be carried out in advance. Concretely, providing a heater for heating the front board 5 with the apparatus, the front board 5 is heated by the heater in advance so that the front board 5 can be in state of the thermal equilibrium from the first etching process. However, this method may decrease productivity of the apparatus because it requires an additional step in making the apparatus available, and because the aging itself takes a long time. Besides, though this method makes the time-average temperature constant, because the front board 5 is used under higher temperature as a whole, the front board 5 probably may suffer thermal damage, shortening its lifetime. If it is intended to cool the front board 5 down to a temperature at which it does not suffer any thermal damage, the cooling mechanism 65 is required to be larger in scale because of the bad thermal contact.

Contrarily, in this embodiment, because the thermal contact is improved, the ultimate temperature during each etching process is lower as shown in FIG. 5(2). The front board 5 reaches the thermal equilibrium within the time of one etching process. The front board 5 is cooled down to the initial temperature to in each etching interval. Therefore, the etching process is repeated in state of the time-average temperature constant as well as smaller temperature change of the front board 5 in each etching process. As a result, not only the etching progress is carried out uniformly in each time of the etching processes, but also reproducibility of the etching can be higher as the etching process is repeated. Additionally, in the apparatus of the embodiment, lifetime of the front board 5 is not shortened because it is used under lower temperatures than the case that the aging is carried out. The productivity does not decrease either because the aging is not carried out.

The above description is about the advantage regarding to the thermal contact. In addition to that, the apparatus of the embodiment has the advantage that the electrical contact of the front board 5 onto the main body 61 is improved. In the case the front board 5 is screwed, the electrical contact probably may be insufficient because the screwing torque cannot be higher. As a result, the plasma may become unstable or insufficient because a required potential is not given to the front board 5. For example, impedance between the front board 5 and the main body 61 increases, causing large HF-energy loss. Contrarily, in this embodiment, the front board 5 can be pressed onto the main body 61 with enough force because it is clamped by the clamping plate 631. Therefore, the sufficient electrical contact of the front board 5 onto the main body 61 is maintained.

Next, the second embodiment of the invention is described about.

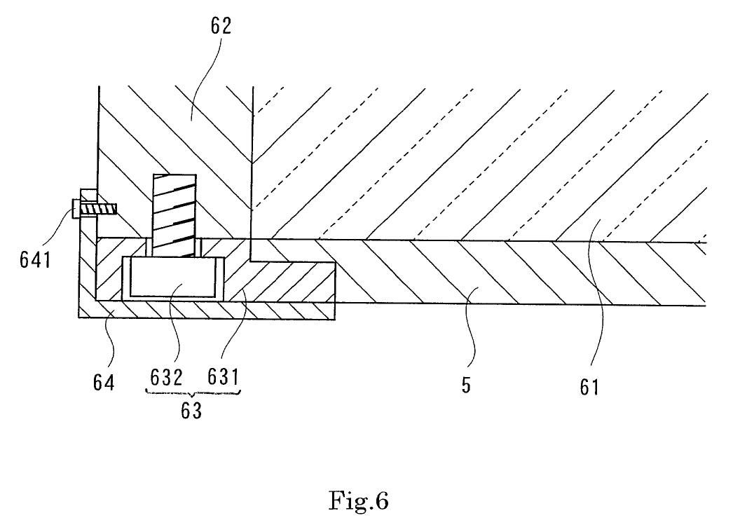

FIG. 6 is a front cross-sectional view of the main part of the plasma-enhanced processing apparatus of the second embodiment. The point characterizing the second embodiment is that the clamping plate 631 is flush with the front board 5. As shown in FIG. 6, a step is provided on the periphery of the front board 5. Thickness of the part of the clamping plate 631 bent to the inside is equal to height of the step. The bent part of the clamping plate 631 is in contact with the step. Also in the second embodiment, the clamping plate 631 is fastened on the insulation casing 62 by the clamping screw 632. The clamping plate 631 and the main body 5 clamp the front board 5 at the periphery.

The reason why the clamping plate 631 is made flush with the front board is that it is intended to improve the plasma characteristics at the space region adjacent to the periphery of the front board 5. As described, the etching process is carried out by generating the plasma between the front board 5 and the substrate 9. For carrying out the etching uniformly onto the substrate 9, it is important to make the plasma uniform along directions parallel to the substrate 9.

In the first embodiment, the clamping plate 631 is not flush with the front board 5. The down surface of the clamping plate 631 is located lower than the front board 5. Beneath the clamping plate 631, the protector 64 is located. Therefore, the structure in the apparatus of the first embodiment does not correspond completely to the parallel-planar-electrodes type because the opposite electrode 6 projects downward at the periphery. In such the structure, the plasma probably may lose uniformity, resulting from distortion of the electric field at the space region adjacent to the projecting part. “Distortion of the electric field” includes distortion of the HF field applied by the HF source and distortion of the sheath field around the plasma.

Contrarily, in the second embodiment, because the clamping plate 631 is flush with the front board 5, only the protector 64 projects downward from the down surface of the front board 5. In other words, the opposite electrode 6 projects less than the first embodiment. Therefore, the problem of the plasma non-uniformity caused from the electric field distortion is suppressed.

Next, the third embodiment of the invention is described about.

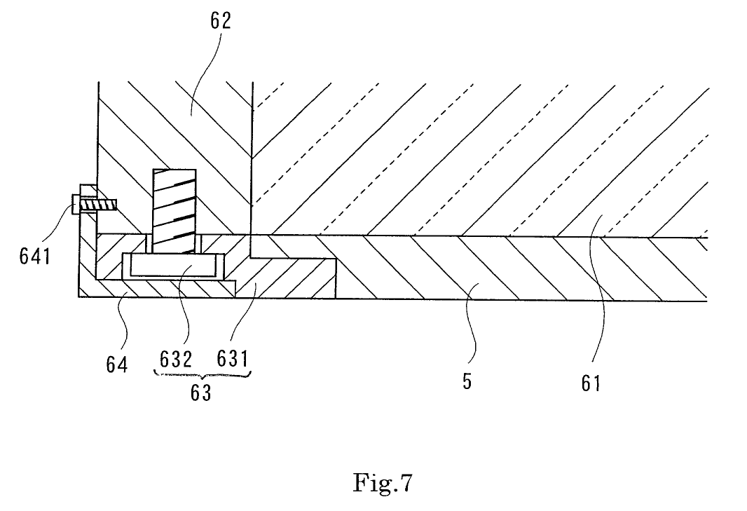

FIG. 7 is a front cross-sectional view of the main part of the plasma-enhanced processing apparatus of the third embodiment. The point characterizing the third embodiment is that both of the clamping plate 631 and the protector 64 are flush with the front board 5.

Concretely, as shown in FIG. 7, the front board 5 has the same step as in the second embodiment. The ring-shaped clamping plate 631 is in contact with the step of the front board 5 at the part bent to the inside, being flush with the front board 5. The clamping plate 631 has a step elongated circumferentially beneath the hole for the clamping screw 632. The ring-shaped protector 64 is provided occupying the step of the clamping plate 631. The protector 64 is in contact with the step at the part bent to the inside, being flush with the clamping plate 631.

Therefore, there is no member projecting downward from the down surface of the opposite electrode 6 in the third embodiment. The structure of the perfect parallel-planar-electrodes type is established. Uniformity of the plasma along directions parallel to the substrate 9 is improved more than the second embodiment, resulting in that uniformity of the etching onto the substrate 9 is improved. The clamping plate 631 is preferably made of material not contaminating the substrate 9, for example silicon mono-crystal, because it probably may be exposed to the plasma.

Next, the fourth embodiment of the invention is described about.

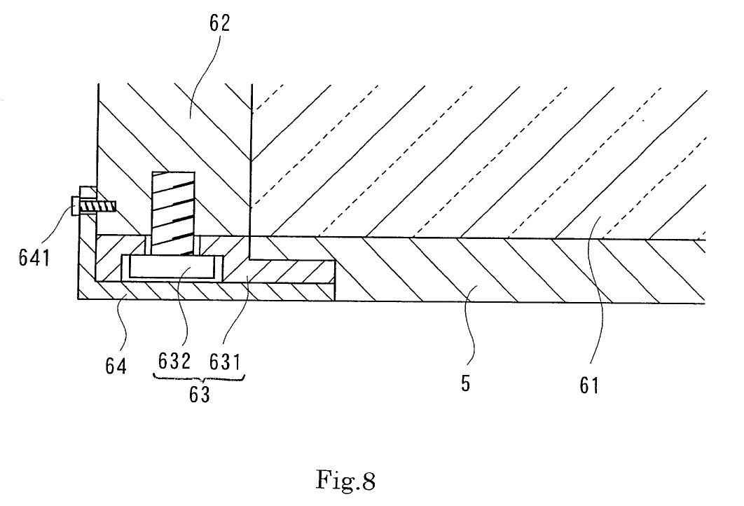

FIG. 8 is a front cross-sectional view of the main part of the plasma-enhanced processing apparatus of the fourth embodiment. The point characterizing the fourth embodiment is that the protector 64 is flush with the front board 5. As shown in FIG. 8, the front board 5 has almost the same step at the periphery as the second and third embodiment. Height of the step is equal to sum of thickness of the level portion of the claming plate 631 and thickness of the level portion of the protector 64. The step of the front board 5 is occupied by the level portion of the claming plate 631 and the level portion of the protector 64. Therefore, the protector 64 is flush with the front board 5.

Also in the fourth embodiment, because of no projecting member, uniformity of the plasma is improved along directions parallel to the substrate 9, thereby enabling to improve uniformity of the etching onto the substrate 9. In addition, in comparison with the third embodiment, this embodiment has the merit that material of the clamping plate 631 is not limited because it is not exposed to the plasma.

The described apparatuses of the embodiments are preferably operated under the condition shown in Table 1.

When the etching is carried out on a BSPG (Boron-doped Phospho-silicate Glass) film deposited on a silicon wafer of 200 mm in diameter under the condition of Table 1, the film can be etched at about 6000 angstrom per minute. “SCCM” in Table 1 means gas flow rate converted at 0° C. and 1 atm, standing for Standard Cubic Centimeter per Minute.

TABLE 1
Preferred Operating Condition

| | |
|---|---|
| Pressure in process chamber | 35 mTorr |
| Process gas | Mixture of C₄F₈, O₂ and Ar |
| Flow rate of process gas | |
| C₄F₈ | 22.5 SCCM |
| O₂ | 10.5 SCCM |
| Ar | 400 SCCM |
| Holder-side HF source | 1.6 MHz, 2000 W |
| Extra HF source | 60 MHz, 1750 W |
| Material of front board | Silicon poly-crystal |
| Thickness of front board | 10 mm |
| Diameter of front board | 285 mm |
| Coolant in main body | Fluorinart |
| Coolant temperature | 20-80° C. |
| Flow rate of coolant | 15 liter/min. |
| Distance of front board and | 24 mm |
| substrate holder | |

The inventor experimentally confirmed that accidents such as the front board breaking did not happen even when it was installed with greater force. This experiment is described using Table 2. In this experiment, two apparatuses were prepared. In the one apparatus, the front board is screwed. In the other apparatus, the front board is clamped by the clamping mechanism as the described apparatus of the embodiments.

Each apparatus was operated under the described condition, varying torque in screwing the front board or torque in screwing the clamping plate. After repeating the etching processes of 2000 times, whether the front board breaking or the screw loosening had happened or not was checked out.

TABLE 2
Comparison of screwing and clamping

| | Screwing | | Clamping | |
|---|---|---|---|---|
| Torque | Front board | Screw | Front board | Screw |
| (Nm) | breaking | loosening | breaking | loosening |
| 0.08 | ∘ | x | ∘ | x |
| 0.5 | x | — | ∘ | x |
| 1.0 | x | — | ∘ | ∘ |
| 1.2 | x | — | ∘ | ∘ |
| 1.5 | x | — | ∘ | ∘ |
| 2.0 | x | — | ∘ | ∘ |

In table 2, “∘” at the “front board breaking” means the front board was not broken, and “×” means the front board was broken. “∘” at the “screw loosening” means the screw did not loosen, and “×” means the screw loosened.

As shown in Table 2, in the structure where the front board is screwed directly on the main body, the front board was broken when it was screwed with torque of 0.5 Nm or more. It means that the front board must be screwed with torque below 0.5 Nm. On the other hand, the screw loosening happened at the 0.08 Nm torque. This was resulted from that the front board and the screw repeated thermal expansion and thermal shrinkage alternatively as the etching process and the etching interval are repeated alternatively. The screw supposedly loosened from difference of thermal expansion coefficient or thermal shrinkage coefficient. It is considered that installation or thermal contact of the front board onto the main body had become much insufficient from such the screw loosening.

Contrarily, as shown in Table 2, in the structure where the front board is clamped by the screwed clamping plate, the front board breaking was not recognized even when the screwing torque was increased up to 2.0 Nm. At the screwing torque of 1.0 Nm or more, no screw loosening was recognized. These results demonstrate that the apparatus of each embodiment can improve thermal contact of the front board onto the main body by pressing the front board onto the main body with greater force.

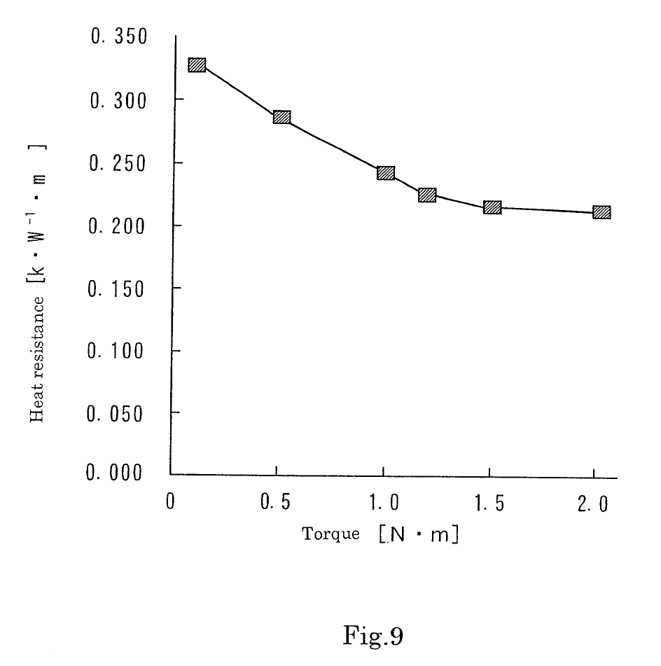

Next, screwing torque for adequate thermal contact is described about using FIG. 9. FIG. 9 shows result of an examination for relationship between screwing torque of the clamping plate and contact of the front board on the main body. In this experiment, heat resistance (KW⁻¹m) between the front board and the main body was measured when the apparatus of the first embodiment was operated under the described condition (Table 1), varying screwing torque of the clamping plate.

As shown in FIG. 9, the heat resistance decreases as the torque is increased, demonstrating improvement of the thermal contact. Decrease of the heat resistance becomes dull around the 1.0 Nm torque, and almost constant at the 1.5 Nm torque or more. These results demonstrate that the screwing torque of 1.0 Nm or more is preferable for securing effects of improvement of thermal contact and prevention of screw loosening.

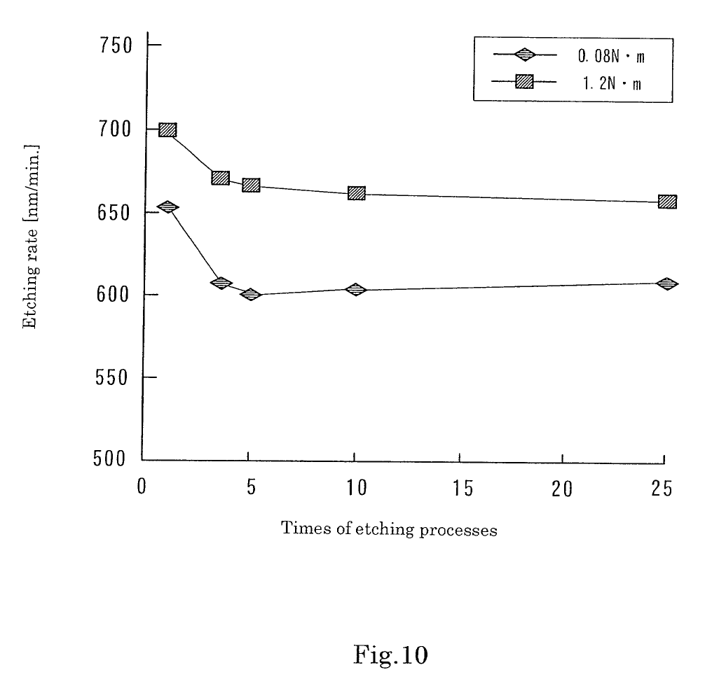

Next is described an examination for relationship between screwing torque of the clamping plate and reproducibility of the etching. FIG. 10 shows result of this examination. In this experiment, the etching rate in the cases of the screwing torque of 0.08 Nm and 1.2 Nm was measured when the etching process was repeated operating the apparatus of the first embodiment under the described condition.

As shown in FIG. 10, in the case of the 0.08 Nm screwing torque, etching rate dropped by the fifth times of the etching process. In other words, reproducibility of the etching decreased largely. This is supposedly resulted from that temperature of the front board, specifically the time-average temperature, rapidly increased because of the bad thermal contact onto the main body. Anyway, this case probably may cause problems such as excessive etching or etching shortage because of low reproducibility. The reason why etching rate in the case of the 0.08 Nm torque is higher than in the case of the 1.2 Nm torque is supposedly that temperature of the substrate was maintained in an adequate range because heat irradiation that the substrate received was reduced, resulting from that the front board was cooled efficiently.

In the described apparatus of each embodiment, material of the front board 5 may be silicon carbide or silicon-impregnated silicon carbide, instead of silicon poly-crystal, silicon mono-crystal, quartz, or carbon. The front board also can be formed of carbon with a silicon carbide film deposited on it, or carbon having a surface inverted to silicon carbide. In addition, the front board 5 can be made of insulator such s silicon nitride, alumina, or sapphire.

There are many compositions of the clamping mechanism 63 other than the described one. For example, the clamping mechanism 63 may be composed of a couple of clamping plate. The claming plate 631 may be pressed onto the front board 5 with an elastic member like spring. The clamping plate 631 may be installed by another means than screwing. Except the front board 5, the clamping plate 631 may be fastened on another member than the main body 61.

The front board 5 and the substrate holder 4 may face in parallel to each other posing vertically. Other than a semiconductor wafer, the substrate 9 may be for a display device such as a liquid crystal display (LCD). The plasma generation means 3 may be one that generates plasma by applying HF voltage to the front board 5, not with the substrate holder 4. If HF voltage is not applied to the substrate holder 4 for plasma generation, no self-bias voltage is given to the substrate 9. Still, that type of apparatus can be used preferably for reactive etching process that does not need to utilize incident ions. HF voltage may be applied to both of the front board 5 and the substrate holder 4. In this case, it is possible to utilize ions incident on the substrate 9 to which the self-bias voltage is given by HF voltage applied to the substrate holder 4, generating plasma by HF voltage applied to front board 5.

This invention can be applied to many kinds of the plasma-enhanced processing apparatuses such as plasma-enhanced chemical vapor deposition (CVD) apparatuses, plasma-enhanced ashing apparatuses and plasma-enhanced surface nitriding apparatuses, other than the described plasma-enhanced etching apparatus. In a plasma-enhanced CVD apparatus, for example, plasma is generated introducing gas capable of deposition, such as gas mixture of silane and hydrogen. In a plasma-enhanced ashing apparatus, plasma is generated introducing gas capable of ashing, such as oxygen.

What is claimed is:

1. A plasma-enhanced processing apparatus, comprising;
a process chamber in which a substrate is processed,
a pumping system that pumps said process chamber,
a gas-introduction system that introduces process gas into said process chamber,
a plasma-generation means that generates plasma in said process chamber by applying energy to said process gas,
a substrate holder that holds said substrate in said process chamber,
wherein an opposite electrode facing to said substrate held by said substrate holder is provided, and the opposite electrode comprises a clamping mechanism that clamps the front board to support said front board.

2. A plasma-enhanced processing apparatus as claimed in claim 1, wherein;
said opposite electrode comprises a main body, and a cooling mechanism that cools said front board via said main body.

3. A plasma-enhanced processing apparatus as claimed in claim 1 or 2, wherein;
said clamping mechanism clamps the periphery of said front board by a clamping plate in surface contact with said front board.

4. A plasma-enhanced processing apparatus as claimed in claim 3, wherein;
said front board has a step at said periphery that is sandwiched by said main board and said clamping plate, and said clamping plate is flush with said front board.

5. A plasma-enhanced processing apparatus as claimed in claim 1, comprising;
a protector covering a surface of said clamping mechanism, wherein said surface is not exposed to said plasma.

6. A plasma-enhanced processing apparatus as claimed in claim 1, wherein;
said clamping mechanism clamps the periphery of said front board by a clamping plate in surface contact on said front board, and said protector is flush with said front board.

7. A plasma-enhanced processing apparatus as claimed in claim 1, 2, 3, 4, 5 or 6, wherein;
said front board is made of silicon poly-crystal or silicon mono-crystal.

8. A plasma-enhanced processing apparatus as claimed in claim 3, wherein;
said clamping plate is screwed on a member except said front board to press said front board onto said main body, and screwing torque is 1 Nm or more.

9. A plasma-enhanced processing apparatus as claimed in claim 6, wherein;
said clamping plate is screwed on a member except said front board to press said front board onto said main body, and screwing torque is 1 Nm or more.

10. A plasma-enhanced processing apparatus as claimed in claim 1, wherein;
a sheet made of carbon is inserted between said main body and said front board.
